(19) United States
(12) Patent Application Publication
(10) Pub. No.: US 2014/0273387 A1
(43) Pub. Date: Sep. 18, 2014

(54) Method Of Making High-Voltage MOS Transistors With Thin Poly Gate

(71) Applicants: Chien-Sheng Su, Saratoga, CA (US); Jeng-Wei Yang, Zhubei (TW); Mandana Tadayoni, Cupertino, CA (US); Yueh-Hsin Chen, Pleasanton, CA (US)

(72) Inventors: Chien-Sheng Su, Saratoga, CA (US); Jeng-Wei Yang, Zhubei (TW); Mandana Tadayoni, Cupertino, CA (US); Yueh-Hsin Chen, Pleasanton, CA (US)

(21) Appl. No.: 13/839,533

(22) Filed: Mar. 15, 2013

(51) Int. Cl. H01L 29/66

(52) U.S. Cl. CPC H01L 29/66477
USPC 438/301

(57) ABSTRACT

A method of forming an MOS transistor by forming a poly gate over and insulated from a substrate, forming a layer of protective insulation material on the poly gate, and then performing a first implant of dopant material into portions of the substrate adjacent the poly gate, wherein the layer of protective insulation material and the poly gate block most or all of the first implant from reaching a portion of the substrate underneath the poly gate. One or more spacers are then formed adjacent the poly gate, followed by a second implant of dopant material into portions of the substrate adjacent to the one or more spacers.

### FIELD OF THE INVENTION

The present invention relates to semiconductor devices, and more particularly to the fabrication of high-voltage MOS Transistors.

### BACKGROUND OF THE INVENTION

FIG. 1 illustrates a partially fabricated conventional MOS transistor, which includes an insulation layer 12 (e.g. oxide) formed over a substrate 10, a polysilicon layer 14 formed over the insulation layer 12, and photo-resist 16 over the polysilicon layer 14. The photo-resist has been patterned, which was followed by a polysilicon etch to result in the structure of FIG. 1 (i.e. a poly gate 14 disposed over and insulated from the substrate 10).

In order to create MOS transistors capable of high voltage operation, it is known to perform a high voltage LDD (lightly doped drain) implant step to the structure of FIG. 1, to lightly dope the source/drain. It is preferred to perform the LDD implant after the formation of the poly gate 14, so that the LDD implant is self-aligned to the poly gate 14. The LDD implant is performed with relative high energy, so the lightly doped region of the LDD region (or junction) extends deep enough into the substrate 10 to achieve a high gated-diode breakdown voltage BVDSS.

As device geometries shrink, including the thickness of poly gate 14 (e.g. less than 1000 Å), the LDD implant can penetrate through the thin poly gate 14, and into the channel region underneath poly gate 14. The implant impurities in that portion of the channel region have the undesirable effect of reducing the maximum operating voltage of the transistor. Lowering the implant energy to avoid LDD implant penetration through the poly gate 14 is also undesirable because that would reduce the gated-diode breakdown voltage.

### BRIEF SUMMARY OF THE INVENTION

The aforementioned problems and needs are addressed by a method of forming an MOS transistor that includes forming a first insulation layer on a substrate, forming a poly layer on the first insulation layer, forming a second insulation layer on the poly layer, selectively removing portions of the second insulation layer and the poly layer to create a poly gate from the poly layer and a layer of protective insulation on the poly gate from the second insulation layer, performing a first implant of dopant material into portions of the substrate adjacent the poly gate, wherein the protective insulation and poly gate block most or all of the first implant from reaching a portion of the substrate underneath the poly gate, forming one or more spacers adjacent the poly gate, and performing a second implant of dopant material into portions of the substrate adjacent to the one or more spacers.

Another aspect of the present invention is a method of forming an MOS transistor that includes providing a substrate, forming a poly gate over and insulated from the substrate, forming a layer of protective insulation material on the poly gate, performing a first implant of dopant material, after the forming of the poly gate and layer of insulation material, into portions of the substrate adjacent the poly gate, wherein the layer of protective insulation material and the poly gate block most or all of the first implant from reaching a portion of the substrate underneath the poly gate, forming one or more spacers adjacent the poly gate, and performing a second implant of dopant material into portions of the substrate adjacent to the one or more spacers.

Other objects and features of the present invention will become apparent by a review of the specification, claims and appended figures.

### BRIEF DESCRIPTION OF THE DRAWINGS

FIG. 1 is a side cross-sectional view of a partially formed conventional MOS transistor.

FIG. 2A-2J are cross sectional views showing in sequence process steps in the formation of a high voltage MOS transistor.

### DETAILED DESCRIPTION OF THE INVENTION

The present invention is a method of manufacturing an MOS transistor that has a thin poly gate yet can be operated at high voltages. The method continues to employ a high voltage LDD implant, and achieves the same high voltage operation characteristics as those transistors with thicker poly gates.

FIGS. 2A-2J show the cross sections of the structure as the processing steps are performed in the manufacture of the high voltage transistor. As illustrated in FIG. 2A, a semiconductor substrate 20 (or a semiconductor well) is provided, which is preferably of P type and is well known in the art. The substrate 20 includes STI insulation regions 22 formed by the well-known process of STI isolation region formation. Alternately, isolation regions 22 could be formed by the well-known LOCOS isolation method. See for example U.S. Pat. No. 6,891,220, which is incorporated herein by reference for all purposes.

A first layer of insulation material 24, such as silicon dioxide (oxide), is deposited or formed on the surface of the substrate between adjacent STI insulation regions 22, as shown in FIG. 2B. The first insulation layer 24 can be formed on the substrate 10 by well-known techniques such as oxidation or deposition (e.g. chemical vapor deposition or CVD), and has a thickness of 100 to 500 Å. A thin layer of polysilicon 26 (hereinafter “poly”) is deposited on top of the first layer of insulation material 24 (e.g. 300 to 1000 Å thick). The deposition and formation of the polysilicon layer 26 on the first insulation layer 24 can be made by a well-known process such as Low Pressure CVD or LPCVD. A sacrificial (second) layer of insulation material 28 (e.g. oxide having a thickness of 200 to 2000 Å) is deposited over the polysilicon layer 26. A photo-resist (masking) material 30 is then deposited over sacrificial oxide layer 28. The resulting structure is shown in FIG. 2C.

A photolithographic step is performed which selectively removes portions of photo-resist 30. Oxide and poly anisotropic etches are performed to remove the exposed portions of sacrificial oxide 28 and poly 26 (i.e. those portions not underneath the remaining portions of photo-resist 30). The photo-resist 30 is then removed, resulting in the structure shown in FIG. 2D.

A second photo-resist 31 is applied, and selectively removed by a photolithography process, leaving the space between adjacent STI regions 22 unobstructed. A high voltage LDD implant process is performed to create lightly doped areas 32 in the substrate between poly gate 26 and STI regions 22, as illustrated in FIG. 2E. As a non-limiting example, the LDD implant is phosphorus with 30 KeV energy for high voltage NMOS transistor. The relatively thick oxide 28 and poly gate 26 minimizes any implantation of dopant from the LDD implant into that portion of the substrate underneath poly gate 26 (i.e. most if not all of the LDD implant is blocked by oxide 28 alone or together with poly gate 26 from reaching the substrate under poly gate 26).

An oxide etch is next performed that removes oxide 28 over poly 26, and removes exposed portions of oxide 24 and STI 22, resulting in the structure of FIG. 2F. The oxide etch can be a wet etch or a dry etch, however a dry etch is preferred to avoid any undesirable undercut issues. The second photo-resist 31 is then removed. Spacers 34 of insulation material (e.g. oxide or nitride) are then formed along the sidewalls of poly gate 26. Formation of spacers is well known in the art, and involves the deposition of a material over the contour of a structure, followed by an anisotropic etch process, whereby the material is removed from horizontal surfaces of the structure, while the material remains largely intact on vertically oriented surfaces of the structure (with a rounded upper surface). The resulting structure is shown in FIG. 2G.

A third photo-resist 35 is applied, and selectively removed by a photolithography process, leaving the space between adjacent STI regions 22 unobstructed. A source/drain implant process is next performed to form source/drain regions 36/38 in the exposed portions of substrate 20 between spacers 34 and STI regions 22, as shown in FIG. 2H. As a non-limiting example, the source/drain implant is a combination of phosphorus 25 KeV, 3E13/cm², arsenic 30 KeV, 2E15, and phosphorus 10 KeV, 1.5E14/cm². The above described method results in graded source/drain regions through the combination of the source/drain implant and the LDD implant which partially overlap each other (i.e. the lightly doped areas 32 created by the LDD implant partially overlaps with the source/drain regions 36/38 created by the source/drain implant, with the non-overlapping portion of the lightly doped areas 32 created by the LDD implant being disposed under spacers 34). The third photo-resist 35 is then removed. A thermal anneal is next performed to activate and drive the high-voltage LDD implant as well as source/drain implant in substrate 22. The resulting LDD junction 32 and source/drain junction 36/38 are shown in FIG. 2I. Since high-voltage LDD implant region 32 and source/drain region 36/38 have the same type of dopant material (N type for NMOS or P type for PMOS), the high-voltage LDD junction and source/drain junction are superimposed as shown in FIG. 2J. After the thermal anneal, the LDD extends its lightly-doped region 32 underneath the poly gate 26. The LDD implant is performed with relative high energy, the lightly doped region of the LDD implant 32 extends deep enough into the substrate 10 to achieve a high gated diode breakdown voltage BVDSS.

It is to be understood that the present invention is not limited to the embodiment(s) described above and illustrated herein, but encompasses any and all variations falling within the scope of the appended claims. For example, references to the present invention herein are not intended to limit the scope of any claim or claim term, but instead merely make reference to one or more features that may be covered by one or more of the claims. Materials, processes and numerical examples described above are exemplary only, and should not be deemed to limit the claims. Further, as is apparent from the claims and specification, not all method steps need be performed in the exact order illustrated or claimed, but rather in any order that allows the proper formation of the MOS transistor of the present invention. Lastly, single layers of material could be formed as multiple layers of such or similar materials, and vice versa.

It should be noted that, as used herein, the terms “over” and “on” both inclusively include “directly on” (no intermediate materials, elements or space disposed therebetween) and “indirectly on” (intermediate materials, elements or space disposed therebetween). Likewise, the term “adjacent” includes “directly adjacent” (no intermediate materials, elements or space disposed therebetween) and “indirectly adjacent” (intermediate materials, elements or space disposed there between). For example, forming an element “over a substrate” can include forming the element directly on the substrate with no intermediate materials/elements therebetween, as well as forming the element indirectly on the substrate with one or more intermediate materials/elements therebetween.

What is claimed is:

1. A method of forming an MOS transistor, comprising:
forming a first insulation layer on a substrate;
forming a poly layer on the first insulation layer;
forming a second insulation layer on the poly layer;
selectively removing portions of the second insulation layer and the poly layer to create a poly gate from the poly layer and a layer of protective insulation on the poly gate from the second insulation layer;
performing a first implant of dopant material into portions of the substrate adjacent the poly gate, wherein the protective insulation and poly gate block most or all of the first implant from reaching a portion of the substrate underneath the poly gate;
forming one or more spacers adjacent the poly gate; and
performing a second implant of dopant material into portions of the substrate adjacent to the one or more spacers.

2. The method of claim 1, wherein the first and second implants partially overlap each other in the substrate.

3. The method of claim 2, wherein:
the second implant creates source and drain regions in the substrate; and
the first implant creates doped areas in the substrate each extending underneath one of the spacers and into one of the source and drain regions.

4. The method of claim 1, further comprising:
removing the layer of protective insulation before the forming of the one or more spacers.

5. The method of claim 1, wherein the selective removing portions of the second insulation layer and the poly layer comprises:
forming photo-resist on the poly layer;
performing a photolithography process to selectively remove some but not all of the photo-resist in a manner leaving some but not all portions of the second insulation layer exposed;
performing an etch process to remove the exposed portions of the second insulation layer leaving some but not all portions of the poly layer exposed; and
performing an etch process to remove the exposed portions of the poly layer.

6. The method of claim 5, further comprising:
removing all of the photo-resist before the performing of the first implant.

7. A method of forming an MOS transistor, comprising:
providing a substrate;
forming a poly gate over and insulated from the substrate;
forming a layer of protective insulation material on the poly gate;
performing a first implant of dopant material, after the forming of the poly gate and layer of insulation material, into portions of the substrate adjacent the poly gate, wherein the layer of protective insulation material and the poly gate block most or all of the first implant from reaching a portion of the substrate underneath the poly gate;
forming one or more spacers adjacent the poly gate; and
performing a second implant of dopant material into portions of the substrate adjacent to the one or more spacers.

8. The method of claim 7, wherein the first and second implants partially overlap each other in the substrate.

9. The method of claim 8, wherein:
the second implant creates source and drain regions in the substrate; and
the first implant creates doped areas in the substrate each extending underneath one of the spacers and into one of the source and drain regions.

10. The method of claim 7, further comprising:
removing the layer of protective insulation before the forming of the one or more spacers.

11. The method of claim 7, wherein the forming of the poly gate and the layer of insulation material comprises:
forming a layer of polysilicon;
forming a layer of insulation on the layer of polysilicon;
forming a layer of photo-resist on the layer of insulation;
performing a photolithography process to selectively remove some but not all of the photo-resist in a manner leaving some but not all portions of the insulation layer exposed;
performing an etch process to remove the exposed portions of the insulation layer leaving some but not all portions of the layer of polysilicon exposed; and
performing an etch process to remove the exposed portions of the layer of polysilicon.

12. The method of claim 11, further comprising:
removing all of the photo-resist before the performing of the first implant.
